(19) United States
(12) Patent Application Publication
(10) Pub. No.: US 2022/0302285 A1
(43) Pub. Date: Sep. 22, 2022

(54) THIN FILM TRANSISTOR AND METHOD FOR MANUFACTURING SAME, DISPLAY PANEL AND DISPLAY DEVICE

(71) Applicants: Fuzhou BOE Optoelectronics Technology Co., Ltd., Fuzhou (CN); BOE Technology Group Co., Ltd., Beijing (CN)

(72) Inventors: Bin LIN, Beijing (CN); Fadian LE, Beijing (CN); Wanxia FU, Beijing (CN); Zhenyou ZOU, Beijing (CN); Hangle GUO, Beijing (CN); Liangliang LI, Beijing (CN)

(21) Appl. No.: 17/692,654

(22) Filed: Mar. 11, 2022

(30) Foreign Application Priority Data
Mar. 19, 2021 (CN) 202110294202.1

(51) Int. Cl. H01L 29/66; H01L 29/417; H01L 29/40

(52) U.S. Cl. CPC H01L 29/66969; H01L 29/41733; H01L 29/401; H01L 27/1214

(57) ABSTRACT

A method for manufacturing a thin film transistor is provided. The method includes: sequentially forming a semiconductor thin film, a patterned source-drain layer and a conductive thin film on a base substrate, performing a patterning process on the semiconductor thin film and the conductive thin film simultaneously to acquire an active layer and a protective electrode layer, and processing the protective electrode layer such that a portion of the protective electrode layer covering the source is insulated from a portion of the protective electrode layer covering the drain.

### CROSS-REFERENCE TO RELATED APPLICATION

This application claims priority to Chinese Patent Application No. 202110294202.1, filed on Mar. 19, 2021 and titled “THIN FILM TRANSISTOR AND METHOD FOR MANUFACTURING SAME, DISPLAY PANEL AND DISPLAY DEVICE”, which is incorporated herein by reference in its entirety.

### TECHNICAL FIELD

The present disclosure relates to the field of display technologies, and in particular, to a thin film transistor and a method for manufacturing the same, a display panel, and a display device.

### BACKGROUND

A thin film transistor (TFT) generally includes a gate, a gate insulating layer, an active layer, a source-drain layer, and a protective electrode layer that are sequentially laminated on a base substrate. The source-drain layer includes a source and a drain which are connected to the active layer, the protective electrode layer includes a first protective electrode covering the source and a second protective electrode covering the drain, and the protective electrode layer and the source-drain layer are formed by a one-time patterning process,

### SUMMARY

Embodiments of the present disclosure provide a thin film transistor and a method for manufacturing the same, a display panel and a display device, Technical solutions are as follows,

According to a first aspect of the embodiments of the present disclosure, method for manufacturing a thin film transistor is provided. The method includes: forming a semiconductor thin film on a base substrate, wherein the semiconductor thin film covers the entire base substrate and is at least configured to form an active layer of the thin film transistor through a patterning process subsequently; forming a patterned source-drain layer on the base substrate formed with the semiconductor thin film, wherein the source-drain layer at least includes a source and a drain of the thin film transistor; forming a conductive thin film on the base substrate formed with the source-drain layer, wherein the conductive thin film covers the entire base substrate and is at least configured to form a protective electrode layer covering the source and the drain through a patterning processing subsequently; and performing the patterning process on the semiconductor thin film and the conductive thin film simultaneously to acquire the active layer formed of the semiconductor thin film and the protective electrode layer formed of the conductive thin film, and processing the protective electrode layer such that a portion of the protective electrode layer covering the source is insulated from a portion of the protective electrode layer covering the drain.

In some embodiments, performing the patterning process on the semiconductor thin film and the conductive thin film simultaneously includes: forming a photoresist layer on the conductive thin film, and performing exposure and development on the photoresist layer to acquire a photoresist pattern, wherein the photoresist pattern is provided with a first photoresist region, a second photoresist region and a photoresist completely-removed region, wherein photoresist in the first photoresist region covers the source and the drain, photoresist in the second photoresist region covers an area between the source and the drain, a thickness of the photoresist in the first photoresist region is greater than a thickness of the photoresist in the second photoresist region, and no photoresist exists in the photoresist completely-removed region; performing wet etching on the semiconductor thin film and the conductive thin film simultaneously to remove a portion, corresponding to the photoresist completely-removed region, of the semiconductor thin film and a portion, corresponding to the photoresist completely-removed region, of the conductive thin film, so as to form the active layer and the protective electrode layer; and removing the photoresist in the second photoresist region and removing a portion, corresponding to the second photoresist region, of the protective electrode layer by dry etching, to form a first protective electrode covering the source and a second protective electrode covering the drain, wherein the first protective electrode and the second protective electrode are disconnected from each other.

In some embodiments, a first orthographic projection of the source on the base substrate is within a second orthographic projection of photoresist covering the source in the first photoresist region on the base substrate, and a distance between an outer boundary of the first orthographic projection and an outer boundary of the second orthographic projection is greater than a preset distance threshold; a third orthographic projection of the drain on the base substrate is within a fourth orthographic projection of photoresist covering the drain in the first photoresist region on the base substrate, and a distance between an outer boundary of the third orthographic projection and an outer boundary of the fourth orthographic projection is greater than a preset distance threshold; and after the protective electrode layer is formed, the protective electrode layer covers a side surface of the source and covers a side surface of the drain.

In some embodiments, a first orthographic projection of the source on the base substrate is within a second orthographic projection of photoresist covering the source in the first photoresist region on the base substrate, and an outer boundary of the first orthographic projection coincides with an outer boundary of the second orthographic projection; a third orthographic projection of the drain on the base substrate is within a fourth orthographic projection of photoresist covering the drain in the first photoresist region on the base substrate, and an outer boundary of the third orthographic projection coincides with an outer boundary of the fourth orthographic projection; and after the protective electrode layer is formed, a side surface of the source away from the drain is flush with one side surface of the protective electrode layer, and a side surface of the drain away from the source is flush with the other side surface of the protective electrode layer.

In some embodiments, the protective electrode layer includes a first portion and a second portion, wherein the first portion is in contact with the source and faces the drain, the second portion is in contact with the drain and faces the source, and the second photoresist region is disposed between the first portion and the second portion; and removing the photoresist in the second photoresist region and removing the portion, corresponding to the second photoresist region, of the protective electrode layer by dry etching includes: removing photoresist between the first portion and the second portion and thinning the photoresist in the first photoresist region by dry etching; and removing a portion, between the first portion and the second portion, of the protective electrode layer by dry etching to expose the active layer, so as to form the first protective electrode and the second protective electrode.

In some embodiments, after removing the portion, between the first portion and the second portion, of the protective electrode layer by dry etching to expose the active layer, the method further includes: performing surface treatment on the active layer with plasma, to adjust concentration of oxygen vacancies in the active layer.

In some embodiments, the plasma includes at least one of oxygen gas and nitrous oxide gas.

In some embodiments, after performing the surface treatment on the active layer with plasma, the method further includes: removing the photoresist in the first photoresist region, and forming a passivation layer on the first protective electrode and the second protective electrode.

In some embodiments, prior to forming the semiconductor thin film on the base substrate, the method further includes: sequentially forming a gate and a gate insulating layer on the base substrate, wherein an orthographic projection of the active layer on the base substrate is within an orthographic projection of the gate on the base substrate.

According to another aspect of the embodiments of the present disclosure, a thin film transistor is provided. The thin film transistor includes: an active layer disposed on a side of a base substrate; a source-drain layer disposed on a side of the active layer away from the base substrate, wherein the source-drain layer at least includes a source and a drain; and a protective electrode layer disposed on a side of the source-drain layer away from the base substrate, wherein the protective electrode layer covers the source and the drain, and a portion of the protective electrode layer covering the source is insulated from a portion of the protective electrode layer covering the drain.

In some embodiments, the protective electrode layer includes a first protective electrode covering the source and a second protective electrode covering the drain, the first protective electrode and the second protective electrode being disconnected from each other.

In some embodiments, the first protective electrode covers a side surface of the source, and the second protective electrode covers a side surface of the drain.

In some embodiments, a side surface of the first protective electrode is flush with a side surface of the source, and a side surface of the second protective electrode is flush with a side surface of the drain.

In some embodiments, a side surface of the first protective electrode away from the second protective electrode is flush with one side surface of the active layer, and a side surface of the second protective electrode away from the first protective electrode is flush with the other side surface of the active layer.

In some embodiments, orthographic projections of the source and the drain on the base substrate are within an orthographic projection of the active layer on the base substrate.

In some embodiments, the thin film transistor further includes: a third protective electrode disposed between the active layer and the source, and a fourth protective electrode disposed between the active layer and the drain.

In some embodiments, a material of the source-drain layer includes metal copper, and a material of the protective electrode layer includes a molybdenum-niobium alloy.

In some embodiments, the thin film transistor further includes: a gate disposed on a side of the active layer close to the base substrate, and a gate insulating layer disposed between the gate and the active layer.

According to yet another aspect of the embodiments of the present disclosure, a display panel is provided. The display panel includes: a base substrate, and a plurality of thin film transistors disposed on the base substrate, wherein the thin film transistor includes: an active layer disposed on a side of the base substrate; a source-drain layer disposed on a side of the active layer away from the base substrate, wherein the source-drain layer at least includes a source and a drain; and a protective electrode layer disposed on a side of the source-drain layer away from the base substrate, wherein the protective electrode layer covers the source and the drain, and a portion of the protective electrode layer covering the source is insulated from a portion of the protective electrode layer covering the drain.

According to still another aspect of the embodiments of the present disclosure, a display device is provided. The display device includes: a power supply assembly and the display panel in the above aspect. The power supply assembly is configured to supply power to the display panel.

### BRIEF DESCRIPTION OF THE DRAWINGS

FIG. 1 is a schematic diagram of a film layer structure of a common thin film transistor at present;

FIG. 2 is a flowchart of a method for manufacturing a thin film transistor according to an embodiment of the present disclosure;

FIG. 3 is a flowchart of another method for manufacturing a thin film transistor according to an embodiment of the present disclosure;

FIG. 4 is a schematic structural diagram of a base substrate in the method shown in FIG. 3;

FIG. 5 is another schematic structural diagram of the base substrate in the method shown in FIG. 3;

FIG. 6 is yet another schematic structural diagram of the base substrate in the method shown in FIG. 3;

FIG. 7 is still another schematic structural diagram of the base substrate in the method shown in FIG. 3;

FIG. 8 is a flowchart of performing a patterning process on a semiconductor thin film and conductive thin film according to an embodiment of the present disclosure;

FIG. 9 is a schematic structural diagram of a base substrate in the method shown in FIG. 8:

FIG. 10 is a schematic structural diagram of a grayscale mask according to an embodiment of the present disclosure;

FIG. 11 is a schematic structural diagram of the base substrate in the method shown in FIG. 8:

FIG. 12 is another schematic structural diagram of the base substrate in the method shown in FIG. 8;

FIG. 13 is yet another schematic structural diagram of the base substrate in the method shown in FIG. 8;

FIG. 14 is still another schematic structural diagram of the base substrate in the method shown in FIG. 8;

FIG. 15 is still another schematic structural diagram of the base substrate in the method shown in FIG. 8;

FIG. 16 is still another schematic structural diagram of the base substrate in the method shown in FIG. 8;

FIG. 17 is still another schematic structural diagram of the base substrate in the method shown in FIG. 8;

FIG. 18 is still another schematic structural diagram of the base substrate in the method shown in FIG. 3;

FIG. 19 is a schematic diagram of a film layer structure of a thin film transistor according to an embodiment of the present disclosure; and

FIG. 20 is a schematic diagram of a film layer structure of another thin film transistor according to an embodiment of the present disclosure.

### DETAILED DESCRIPTION

Embodiments of the present disclosure are described in further detail with reference to the accompanying drawings, to make the objects, technical solutions and advantages of the present disclosure clearer.

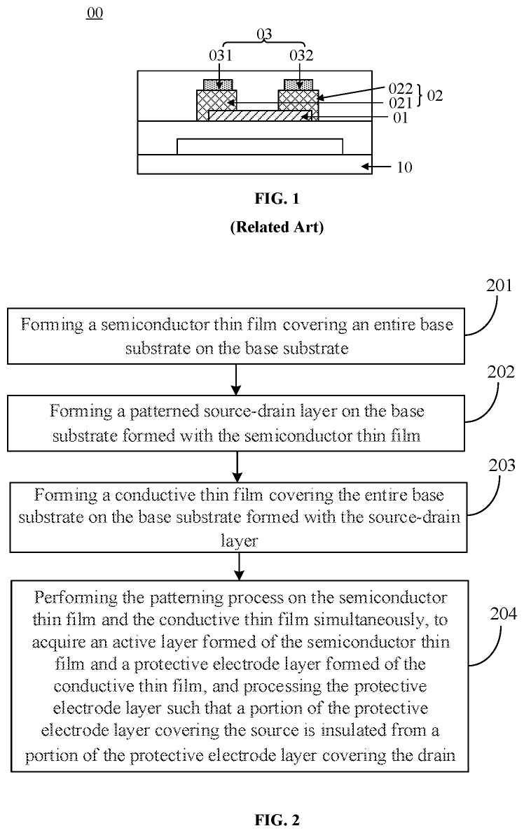

Reference is made to FIG. 1, which is a schematic diagram of a film layer structure of a common thin film transistor at present. A thin film transistor 00 may include: an active layer 01 disposed on a side of a base substrate 10, a source-drain layer 02 disposed on a side of the active layer 01 away from the base substrate 10, and a protective electrode layer 03 disposed on a side of the source-drain layer 02 away from the base substrate 10.

The source-drain layer 02 includes a source 021 and a drain 022 which are connected to the active layer 01. The protective electrode layer 03 includes a first protective electrode 031 covering the source 021 and a second protective electrode 031 covering the drain 022. In order to simplify the manufacturing process of the thin film transistor 00. the protective electrode layer 03 and the source-drain layer 02 in the thin film transistor 00 are usually formed by a one-time patterning process. The one-time patterning process generally includes photoresist coating, exposure, development, etching and photoresist stripping.

During the etching process in the one-time patterning process, the lateral etching rate of the protective electrode layer 03 is greater than the lateral etching rate of the source-drain layer 02. Therefore, during the etching process, over-etching easily occurs in the protective electrode layer 03, which results in that a portion of the source-drain layer 02 is not covered by the protective electrode layer 03. The portion, not covered by the protective electrode layer 03, of the source-drain layer 02 is easily oxidized, which affects the conductivity of the source-drain layer 02 and results in poor performance of the thin film transistor 00.

Reference is made to FIG. 2, which is a flowchart of a method for manufacturing a thin film transistor according to an embodiment of the present disclosure. The method for manufacturing a thin film transistor may include the following steps.

In step 201, a semiconductor thin film covering an entire base substrate is formed on the base substrate.

The semiconductor thin film is at least configured to form an active layer of the thin film transistor subsequently through a patterning process.

In step 202, a patterned source-drain layer is formed on the base substrate formed with the semiconductor thin film.

The source-drain layer at least includes a source and a drain of the thin film transistor.

In step 203, a conductive thin film covering the entire base substrate is formed on the base substrate formed with the source-drain layer.

The conductive thin film is at least configured to form a protective electrode layer covering the source and the drain subsequently through a patterning process.

In step 204, the patterning process is performed on the semiconductor thin film and the: conductive thin film simultaneously, to acquire an active layer formed of the semiconductor thin film and a protective electrode layer formed of the conductive thin film, and the protective electrode layer is processed such that a portion of the protective electrode layer covering the source is insulated from a portion of the protective electrode layer covering the drain.

In summary, the embodiment of the present disclosure provides a method for manufacturing a thin film transistor. In this method, the protective electrode layer and the active layer are formed by a one-time patterning process, and the protective electrode layer and the source-drain layer are formed by different patterning processes. In this way, the formed protective electrode layer can cover the source-drain layer without increasing the difficulty of the process, which reduces the probability of the source-drain layer being oxidized and improves the conductivity of the source-drain layer, thereby improving the performance of the thin film transistor.

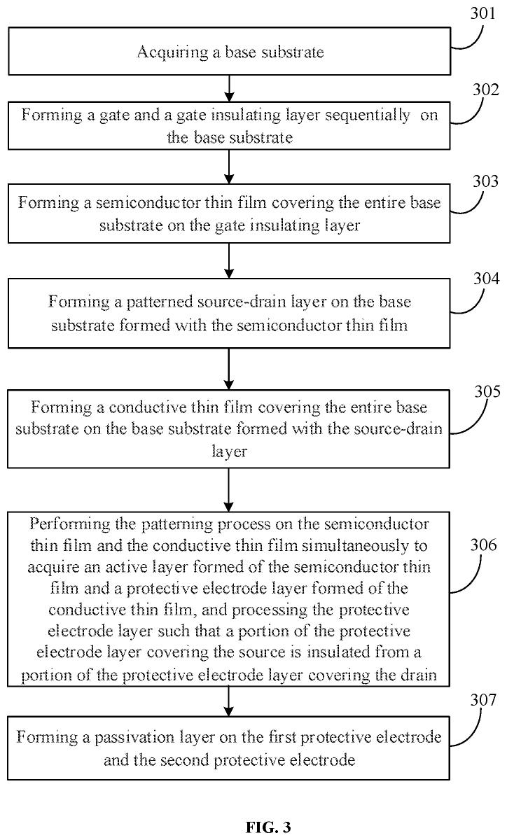

FIG. 3 is a flowchart of another method for manufacturing a thin film transistor according to an embodiment of the present disclosure. The method for manufacturing the thin film transistor may include the following steps.

In step 301, a base substrate is acquired.

The material of the base substrate may include glass, polyimide, or the like.

In step 302, a gate and a gate insulating layer are sequentially formed on the base substrate.

The gate may be a structure in a thin film transistor. When the gate is formed, a gate metal layer may be first formed on the base substrate (the gate metal layer may be formed by one of deposition, sputtering, and the like), and then a patterning process is performed on the gate metal layer to acquire the gate. It should be noted that, a gate pattern including a plurality of gates may be acquired through the patterning process. For some or all of the gates in the gate pattern, reference may be made to the gates in the embodiments of the present disclosure. In the embodiments of the present disclosure, the patterning process may include photoresist coating, exposure, development, etching, photoresist stripping and the like.

When the gate insulating layer is formed, the gate insulating layer may be formed by deposition. The gate insulating layer may be configured to avoid short circuit between the gate and other structures in the thin film transistor.

For example, FIG. 4 is a schematic structural diagram of the base substrate after step 302 is executed. As shown in FIG. 4, the gate 112 is formed on the base substrate 111, and the gate insulating layer 113 is formed on the base substrate 111 with the gate 112. The material of the gate 112 may include metal materials such as metal aluminum, metal copper or an alloy. The material of the gate insulating layer 113 may include silicon dioxide, silicon nitride, or a mixed material of silicon dioxide and silicon nitride.

In step 303, a semiconductor thin film covering the entire base substrate is formed on the gate insulating layer.

The semiconductor thin film may be formed by deposition. The material of the semiconductor thin film may include an oxide semiconductor material. For example, the oxide semiconductor material may be: Indium Gallium Zinc Oxide (IGZO). In the present disclosure, the semiconductor thin film is at least configured to form the active layer of the thin film transistor subsequently through a patterning process,

For example, FIG. 5 is another schematic structural diagram of the base substrate at the end of step 303. As shown in FIG. 5, the semiconductor thin film 114 is formed on the base substrate 111 formed with the gate insulating layer 113.

In step 304, a patterned source-drain layer is formed on the base substrate formed with the semiconductor thin film.

Forming the patterned source-drain layer on the base substrate formed with the semiconductor thin film may include: forming a source-drain metal layer on the base substrate formed with the semiconductor thin film, and performing a patterning process on the source-drain metal layer, to acquire the source-drain layer. The source-drain layer at least includes a source and a drain of the thin film transistor. In the embodiments of the present disclosure, the patterning process may include: photoresist coating, exposure, development, etching, photoresist stripping and the like.

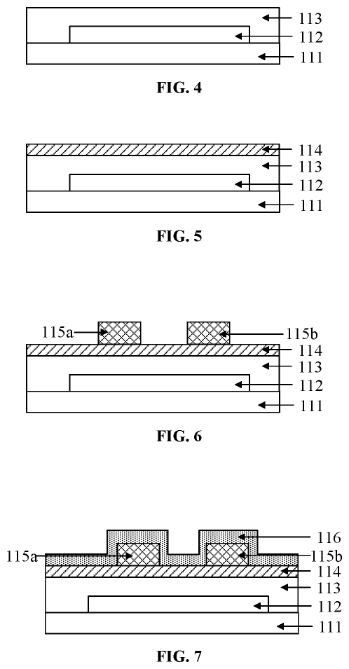

For example, FIG. 6 is another schematic structural diagram of the base substrate after step 304 is executed. As shown in FIG. 6, a source-drain metal layer is formed on the base substrate 111 formed with the semiconductor thin film 114, and the one-time patterning process is performed on the source-drain metal layer, to form a source-drain layer. The source-drain layer at least includes the source 115a and the drain 115b of the thin film transistor. The material of the source-drain layer 115 may include a metal material such as metal aluminum, metal silver, metal copper, or an alloy.

Currently, in common thin film transistors, the source-drain layer and the protective electrode layer are formed by a one-time patterning process. First, a source-drain metal layer and a protective electrode metal layer are sequentially formed on the active layer. Next, a photoresist thin film is formed on the protective electrode metal layer, and exposure and development are performed on the photoresist thin film. Then, the source-drain metal layer and the protective electrode metal layer are etched to form the source-drain layer and the protective electrode layer. Finally, the photoresist is stripped off. The material of the protective electrode layer may include a metal material such as metal titanium, a molybdenum-titanium alloy or a molybdenum-niobium alloy.

When the protective electrode layer is made from a molybdenum-niobium alloy, the photoresist on the protective electrode metal layer falls off easily during the patterning process due to the poor adhesion of the molybdenum-niobium alloy to the photoresist, which results in over-etching of the source-drain metal layer, thereby affecting the yield of the thin film transistor.

In the present disclosure, the source-drain layer is formed through the above step 304, that is, the source-drain layer is formed through an individual one-time patterning process. In this way, over-etching of the source-drain metal layer due to the photoresist peeling during the patterning process can be avoided, thereby improving the yield of the thin film transistor.

In other implementations, forming the patterned source-drain layer on the base substrate formed with the semiconductor thin film may further include: sequentially forming a conductive metal layer and a source-drain metal layer on the base substrate formed with the semiconductor thin film, and performing the patterning process on the conductive metal layer and the source-drain metal layer to acquire a third protective electrode, a fourth protective electrode, a source and a drain. The third protective electrode is disposed between the semiconductor thin film and the source, the fourth protective electrode is disposed between the semiconductor thin film and the drain. The third protective electrode and the fourth protective electrode are configured to protect the semiconductor thin film and prevent metal ions in the source and the drain from diffusing into the semiconductor thin film, thereby preventing the performance of the active layer subsequently formed based on the semiconductor thin film from being affected. In the embodiments of the present disclosure, the patterning process may include: photoresist coating, exposure, development, etching, photoresist stripping and the like.

In step 305, a conductive thin film covering the entire base substrate is formed on the base substrate formed with the source-drain layer.

In the present disclosure, the conductive thin film may be formed by deposition. The conductive thin film is at least configured to form a protective electrode layer covering the source and the drain through a patterning process subsequently. The material of the conductive thin film may include a conductive material such as metal molybdenum, metal titanium, a molybdenum-titanium alloy or a molybdenum-niobium alloy. For example, the material of the conductive thin film may be metal molybdenum.

For example, FIG. 7 is another schematic structural diagram of the base substrate after step 305 is executed. As shown in FIG. 7, a conductive thin film 116 is formed on the base substrate 111 formed with the source-drain layer.

In step 306, the patterning process is performed on the semiconductor thin film and the conductive thin film simultaneously to acquire an active layer formed of the semiconductor thin film and a protective electrode layer formed of the conductive thin film, and the protective electrode layer is processed such that a portion of the protective electrode layer covering the source is insulated from a portion of the protective electrode layer covering the drain.

FIG. 8 is a flowchart of simultaneously performing a patterning process on the semiconductor thin film and conductive thin film according to an embodiment of the present disclosure. As shown in FIG. 8, step 306 may include the following four sub-steps.

In sub-step 3061, a photoresist layer is formed on the conductive thin film.

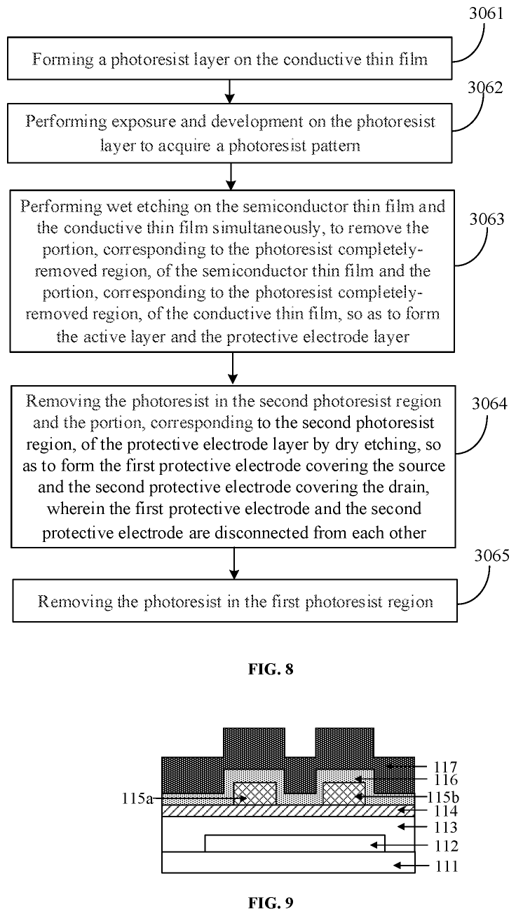

For example, FIG. 9 is a schematic structural diagram of the base substrate after sub-step 3061 is executed. As shown in FIG. 9, a photoresist layer 117 is formed on the conductive thin film 116.

In step 3062, exposure and development are performed on the photoresist layer to acquire a photoresist pattern.

The photoresist pattern is provided with a first photoresist region, a second photoresist region, and a photoresist completely-removed region. Here, photoresist in the first photoresist region covers the source and the drain; photoresist in the second photoresist region covers the area between the source and the drain; and no photoresist exists in the photoresist completely-removed region. In the present disclosure, the thickness of the photoresist in the first photoresist region is greater than the thickness of the photoresist in the second photoresist region.

In the embodiments of the present disclosure, the process of forming the photoresist pattern may include: performing exposure and development on the photoresist layer by using a. grayscale mask, to retain the photoresist covering the source and the drain and the photoresist between the source and the drain while remove photoresist in other areas. Here, the photoresist covering the source and the drain is the photoresist in the first photoresist region; and the photoresist between the source and the drain is the photoresist in the second photoresist region.

The photoresist is a bearing medium for optical patterning. The photoresist serves to convert optical information after diffraction and filtering in a lithography system into chemical energy according to the principle of photochemical reaction, so as to complete the duplication of a mask pattern.

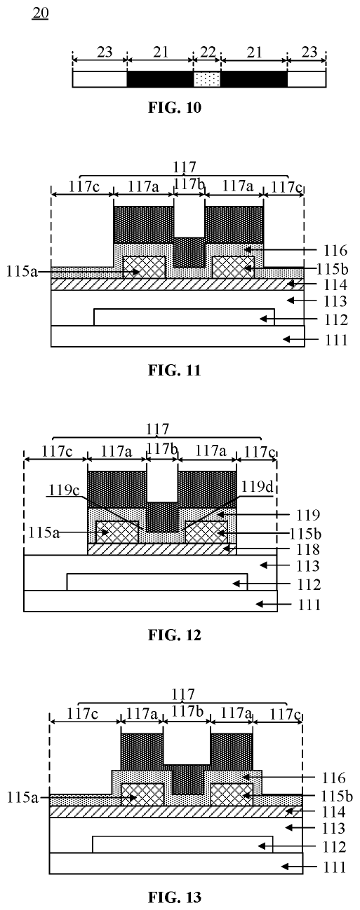

FIG. 10 is a schematic structural diagram of a grayscale mask according to an embodiment of the present disclosure. As shown in FIG. 10, the grayscale mask 20 may include a non-light-transmitting region 21, a semi-light-transmitting region 22 and a light-transmitting region 23. The transmittance of the non-light-transmitting region 21 is smaller than that of the semi-light-transmitting region 22, and the transmittance of the semi-light-transmitting region 22 is smaller than that of the light-transmitting region 23. By taking an example in which the material of the photoresist layer is positive photoresist, after exposure and development are performed on the photoresist layer, the photoresist in the first photoresist region and the photoresist in the second photoresist region may be retained, the photoresist in the photoresist completely-removed region is removed, and the thickness of the photoresist in the first photoresist region is greater than the thickness of the photoresist in the second photoresist region. The first photoresist region corresponds to the non-light-transmitting region 21 in the grayscale mask 20, the second photoresist region corresponds to the semi-light-transmitting region 22 in the grayscale mask 20, and the photoresist completely-removed region corresponds to the light-transmitting region 23 in the grayscale mask 20.

It should be noted that the embodiments of the present disclosure are schematically illustrated by taking an example in which the material of the photoresist thin film is positive photoresist. In other optional implementations, the material of the photoresist thin film may also be negative photoresist, which is not limited in embodiments of the present disclosure.

For example, FIG. 11 is a schematic structural diagram of the base substrate after sub-step 3062 is executed. As shown in FIG. 11, exposure and development are performed on the photoresist layer 117 by using a grayscale mask 20, to retain the photoresist in the first photoresist region 117a and the photoresist in the second photoresist region 117b while remove the photoresist in the photoresist completely-removed region 117c, and the thickness of the photoresist in the first photoresist region 117a is greater than the thickness of the photoresist in the second photoresist region 117b.

In sub-step 3063, wet etching is performed on the semiconductor thin film and the conductive thin film simultaneously, to remove the portion, corresponding to the photoresist completely-removed region, of the semiconductor thin film and the portion, corresponding to the photoresist completely-removed region, of the conductive thin film, so as to form the active layer and the protective electrode layer.

In the present disclosure, wet etching may be simultaneously performed on the semiconductor thin film and the conductive thin film corresponding to the photoresist completely-removed region, to remove the portion, corresponding to the photoresist completely-removed region, of the semiconductor thin film and the portion, corresponding to the photoresist completely-removed region, of the conductive thin film, so as to form the active layer and the protective electrode layer. An orthographic projection of the active layer on the base substrate is within an orthographic projection of the gate on the base substrate.

The wet etching process refers to performing etching process on the semiconductor thin film and the conductive thin film by using an etchant.

In the embodiments of the present disclosure, there are various possible implementations for the positional relationship between the photoresist in the first photoresist region and the source and the drain, and the shape of the formed protective electrode layer also has various possible implementations. In the embodiments of the present disclosure, the following two possible implementations are illustratively described as examples:

In a first possible implementation, as shown in FIG. 11, the first orthographic projection of the source 115a on the base substrate 111 is within the second orthographic projection of the photoresist covering the source 115a in the first photoresist region 117a on the base substrate 111, and the distance between the outer boundary of the first orthographic projection and the outer boundary of the second orthographic projection is greater than a preset distance threshold. The third orthographic projection of the drain 115b on the base substrate 111 is within the fourth orthographic projection of the photoresist covering the drain 115b in the first photoresist region 117a on the base substrate 111, and the distance between the outer boundary of the third orthographic projection and the outer boundary of the fourth orthographic projection is greater than a preset distance threshold. In this case, as shown in FIG. 12. which is another schematic structural diagram of the base substrate after sub-step 3063 is executed, after the portion, corresponding to the photoresist completely-removed region 117c, of the semiconductor thin film 114 and the portion, corresponding to the photoresist completely-removed region 117c, of the conductive thin film 116 are removed, the orthographic projection of the acquired active layer 118 on the base substrate 111 is within the orthographic projection of the gate 112 on the base substrate 111, and the acquired protective electrode layer 119 may cover the side surfaces of the source 115a and may cover the side surfaces of the drain 115b. In this way, after the first protective electrode covering the source 115a and the second protective electrode covering the drain 115b are formed based on the protective electrode layer 119 subsequently, each surface of the source 115a may be protected by the first protective electrode, and each surface of the drain 115b may be protected by the second protective electrode.

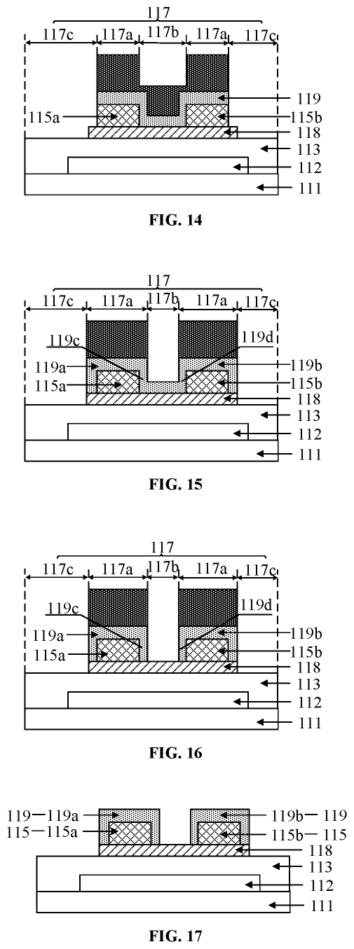

In a second possible implementation, as shown in FIG. 13, which is another schematic structural diagram of the base substrate after sub-step 3062 is executed, the first orthographic projection of the source 115a on the base substrate 111 is within the second orthographic projection of the photoresist covering the source 115a in the first photoresist region 117a on the base substrate 111, and the outer boundary of the first orthographic projection coincides with the outer boundary of the second orthographic projection. The third orthographic projection of the drain 115b on the base substrate 111 is within the fourth orthographic projection of the photoresist covering the drain 115b in the first photoresist region 117a on the base substrate 111, and the outer boundary of the third orthographic projection coincides with the outer boundary of the fourth orthographic projection. In this case, as shown in FIG. 14, which is another schematic structural diagram of the base substrate after sub-step 3063 is executed, after the portion, corresponding to the photoresist completely-removed region 117c, of the semiconductor thin film 114 and the portion, corresponding to the photoresist completely-removed region 117c, of the conductive thin film 116 are removed, the orthographic projection of the acquired active layer 118 on the base substrate 1.11 is within the orthographic projection of the gate 112 on the base substrate 111, one side surface of the acquired protective electrode layer 119 is flush with the side surface of the source 115a away from the drain 115b, and the other side surface of the protective electrode layer 119 is flush with the side surface of the drain 115b away from the source 115a.

It should be noted that the following embodiments of the present disclosure are schematically illustrated by taking the first possible implementation as an example.

In sub-step 3064, the photoresist in the second photoresist region and the portion, corresponding to the second photoresist region, of the protective electrode layer are removed by dry etching, so as to form the first protective electrode covering the source and the second protective electrode covering the drain. The first protective electrode and the second protective electrode are disconnected from each other.

As shown in FIG. 12, the protective electrode layer 119 includes a first portion 119c and a second portion 119d. The first portion 119c is a portion, in contact with the source 115a and facing the drain 115b, of the protective electrode layer 119; the second portion 119d is a portion, in contact with the drain 115b and facing the source 115a, of the protective electrode layer 119. The second photoresist region 117b is disposed between the first portion 119c and the second portion 119d.

This sub-step 3064 may include the following steps.

In step A1, the photoresist between the first portion and the second portion is removed and the photoresist in the first photoresist region is thinned by dry etching.

In the present disclosure, the base substrate formed with the protective electrode layer may be placed in a dry etching chamber, and ashing gas may be injected. such that the photoresist between the first portion and the second portion is removed and the photoresist in the first photoresist region is thinned by using the ashing gas. The ashing gas is used to react with the photoresist so as to remove the photoresist on the base substrate. For example, the ashing gas may include a mixed gas of oxygen and sulfur hexafluoride.

For example, as shown in FIG. 15, which is still another schematic structural diagram of the base substrate after step A1 is executed, the photoresist disposed between the first portion 119c and the second portion 119d is removed and the photoresist in the first photoresist region 117a is thinned by dry etching.

In step A2, the portion, between the first portion and the second portion, of the protective electrode layer is removed by dry etching to expose the active layer, so as to form the first protective electrode and the second protective electrode.

In the present disclosure, the portion, between the first portion and the second portion, of the protective electrode layer may he removed by dry etching to expose the active layer, so as to form the first protective electrode and the second protective electrode. In this way, the first protective electrode may completely cover the side surfaces of the source, and the formed second protective electrode may completely cover the side surfaces of the drain. Therefore, in the subsequent process of depositing a film layer on the first protective electrode and the second protective electrode, the side surfaces of the source and the side surfaces of the drain can be prevented from being bombarded by plasma, thereby preventing metal ions in the source and the drain from diffusing to a channel of the active layer, and further ensuring the performance of the thin film transistor.

The dry etching process refers to a process of etching the conductive thin film in a. dry etching chamber by using plasma. By the dry etching process, the etching rate of the conductive thin film may be better controlled, thereby reducing the probability of over-etching of the conductive thin film. Therefore, it is ensured that the protective electrode layer can cover the source-drain layer, thereby preventing the source-drain layer from being oxidized, and improving the conductivity of the source-drain layer. Optionally, the plasma may be a mixed gas of oxygen and sulfur hexafluoride.

For example, as shown in FIG. 16, which is still another schematic structural diagram of the base substrate after step A2 is executed, the portion, between the first portion 119c and the second portion 119d, of the protective electrode layer 119 is removed by dry etching to expose the active layer 118, so as to form the first protective electrode 119a and the second protective electrode 119b.

In step A3, surface treatment is performed on the active layer by using plasma.

Optionally, the plasma may include at least one of oxygen gas and nitrous oxide gas. In the present disclosure, the plasma may be adopted to perform surface treatment on the active layer to adjust the concentration of oxygen vacancies in the active layer, such that the concentration of oxygen vacancies in the active layer is higher, thereby reducing an ohmic contact resistance between the active layer and the source-drain layer, and further improving the performance of the thin film transistor,

It should be noted that the above steps A1 to A3 may be performed in the same dry etching chamber.

In sub-step 3065, the photoresist in the first photoresist region is removed.

The photoresist in the first photoresist region may be removed by stripping.

For example, as shown in FIG. 17, which is still another schematic structural diagram of the base substrate after sub-step 3065 is executed, the photoresist in the first photoresist region 117c is removed by stripping.

In step 307, a passivation layer is formed on the first protective electrode and the second protective electrode.

The passivation layer may be formed by chemical vapor deposition with plasma. The passivation layer may not only protect the thin film transistor to prevent the structure in the thin film transistor from being polluted by water vapor and impurities, but also avoid short circuit between the thin film transistor and a pixel electrode in a display panel subsequently formed.

Optionally, the plasma may be a mixed gas of nitrous oxide gas and silane gas.

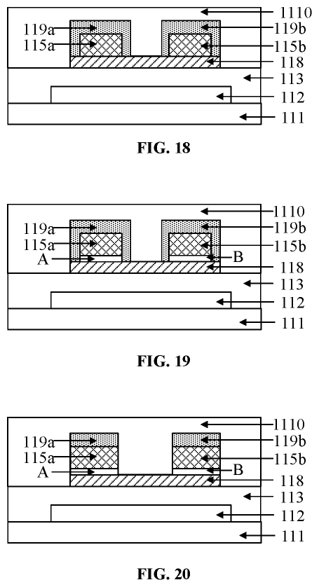

For example, as shown in FIG. 18, which is still another schematic structural diagram of the base substrate after step 307 is executed, a passivation layer 1110 is formed on the first protective electrode 119a and the second protective electrode 119b. The material of the passivation layer 1110 may include silicon dioxide, silicon nitride or a mixed material of silicon dioxide and silicon nitride.

It should be noted that, through the above steps 301 to 307, a bottom-gate thin film transistor may be formed.

In summary, the embodiments of the present disclosure provide a method for manufacturing a thin film transistor. In this method, the protective electrode layer and the active layer are formed by a one-time patterning process, and the protective electrode layer and the source-drain layer are formed by different patterning processes. In this way, the formed protective electrode layer can cover the source-drain layer without increasing the difficulty of the process, which reduces the probability of the source-drain layer being oxidized and improves the conductivity of the source-drain layer, thereby improving the performance of the thin film transistor.

An embodiment of the present disclosure further provides a thin film transistor. The thin film transistor may be manufactured by the method for manufacturing a thin film transistor in the above embodiments. For example, reference may be made to FIG. 19 or FIG. 20 for the structure of the thin film transistor. FIG. 19 is a schematic diagram of a film layer structure of a thin film transistor according to an embodiment of the present disclosure, and FIG. 20 is a schematic diagram of a film layer structure of still another thin film transistor according to an embodiment of the present disclosure. The thin film transistor may include: an active layer 118 on a side of the base substrate 111;

a source-drain layer 115 disposed on a side of the active layer 118 away from the base substrate 111, wherein the source-drain layer 115 at least includes a source 115a and a drain 115b and

a protective electrode layer 119 disposed on a side of the source-drain layer 115 away from the base substrate 111, wherein the protective electrode layer 119 covers the source 115a and the drain 115b, and a portion of the protective electrode layer 119 covering the source 115a is insulated from a portion of the protective electrode layer 119 covering the drain 115b.

In the embodiment of the present disclosure, as shown in FIG. 19 and FIG. 20, the protective electrode layer in the thin film transistor may include: a first protective electrode 119a covering the source 115a and a second protective electrode 119b covering the drain 115b, and the first protective electrode 119a and the second protective electrode 119b are disconnected from each other. The side of the first protective electrode 119a away from the second protective electrode 119b may be flush with one side surface of the active layer 118, and the side of the second protective electrode 119b away from the first protective electrode 119a may be flush with the other side surface of the active layer 118.

In the present disclosure, the shape of the first protective electrode 119a and the shape of the second protective electrode 119b have a plurality of possible implementations, and the embodiments of the present disclosure are schematically illustrated by taking the following two possible implementations as examples.

In a first possible implementation, as shown in FIG. 19, the first protective electrode 119a covers the side surfaces of the source 115a, and the second protective electrode 119b covers the side surfaces of the drain 115b. In this way, the first protective electrode 119a may completely cover the side surfaces of the source 115a, and the second protective electrode 119b may completely cover the side surfaces of the drain 115b. Therefore, in a subsequent process of depositing a film layer on the first protective electrode 119a and the second protective electrode 119b, the side surfaces of the source 115a, and the side surfaces of the drain 115b can be prevented from being bombarded by plasma, thereby preventing metal ions in the source 115a and the drain 115b from diffusing to a channel of the active layer 118. and further ensuring the performance of the thin film transistor.

In a second possible implementation, as shown in FIG. 20, the side surface of the first protective electrode 119a is flush with the side surface of the source 115a, and the side surface of the second protective electrode 119b is flush with the side surface of the drain 115b. In this way, the first protective electrode 119a may cover the source 115a and the second protective electrode 119b may cover the drain 115b, which reduces the probability of the source 115a and the drain 115b being oxidized, and improves the conductivity of the source 115a and the drain 115b, thereby improving the performance of the thin film transistor.

In the present disclosure, as shown in FIG. 19 and FIG. 20, orthographic projections of the source 115a and the drain 15b on the base substrate 111 are within an orthographic projection of the active layer 118 on the base substrate 111. In this way, the source 115a and the drain 115b do not need to climb on the active layer 118, thereby preventing the source 115a and the drain 115b from breaking due to a step difference. and further ensuring the performance of the thin film transistor.

In the embodiment of the present disclosure, as shown in FIG. 19 and FIG. 20, the thin film transistor may further include: a. third protective electrode A disposed between the active layer 118 and the source 115a, and a fourth protective electrode B disposed between the active layer 118 and the drain 115b. The third protective electrode A and the fourth protective electrode B may be configured to protect the active layer 118 and prevent metal ions in the source 115a, and the drain 115b from diffusing into the active layer 118.

In the present disclosure, as shown in FIG. 19 and FIG. 20, the thin film transistor may further include: a gate 112 disposed on a side of the active layer 118 close to the base substrate 111, and a gate insulating layer 113 disposed between the gate 112 and the active layer 118. An orthographic projection of the active layer 118 in the thin film transistor on the base substrate 111 is within an orthographic projection of the gate 112 on the base substrate 111, and the active layer 118 is insulated from the gate 112 by means of the gate insulating layer 113.

Optionally, the material of the source-drain layer 115 may include: metallic copper; and the material of the protective electrode layer 119 may include: a molybdenum-niobium alloy.

Optionally, the thin film transistor may further include a passivation layer 1110 disposed on the side of the protective electrode layer 119 away from the base substrate 111.

Those skilled in the art may clearly understand that, for the convenience and brevity of descriptions, reference may be made to the corresponding content in the aforementioned embodiment of the method for manufacturing a thin film transistor for the principle of each component in the above-described thin film transistor, and details are not repeated here.

In summary, the embodiment of the present disclosure provides a thin film transistor, In the thin film transistor, the protective electrode layer may cover the source-drain layer, which reduces the probability of the source-drain layer being oxidized, and improves the conductivity of the source-drain layer, thereby further improving the performance of the thin film transistor. In addition, since the source-drain layer is completely covered by the protective electrode layer, in the subsequent process of depositing a film layer on the protective electrode layer, the side surfaces of the source-drain layer can be prevented from being bombarded by plasma, thereby preventing metal ions in the source-drain layer from diffusing to a channel of the active layer, and further ensuring the performance of the thin film transistor,

An embodiment of the present disclosure further provides a display panel. The display panel may include: a base substrate, and a plurality of thin film transistors as shown in FIG. 19 or FIG. 20 disposed on the base substrate. The display panel may be a liquid crystal display panel and an organic light-emitting diode (OLED) display panel. When the display panel is a liquid crystal display panel, the thin film transistor may be integrated in an array substrate in the liquid crystal display panel.

An embodiment of the present disclosure further provides a display device. The display device may include a power supply assembly and the above-mentioned display panel. The power supply assembly is configured to supply power to the display panel. The display device may be any product or component with a display function, such as a liquid crystal panel, electronic paper, a mobile phone, a tablet computer, a television, a display, a notebook computer, a digital photo frame, a navigator, or the like.

It should be noted that in the accompanying drawings, for clarity of the illustration, the dimension of the layers and regions may be scaled up. it may be understood that when an element or layer is described as being “on” another element or layer, the described element or layer may be directly on the other element or layer, or an intermediate layer may exist. In addition, it may be understood that when an element or layer is described as being “under” another element or layer, the described element or layer may be directly below the other element or layer, or at least one intermediate layer may exist. In addition, it may be further understood that when a layer or element is described as being arranged “between” two layers or elements, the described layer or element may be the only layer between the two layers or elements, or at least one intermediate layer or element may exist. In the whole specification, like reference numerals denote like elements.

In the present application, the terms “first” and “second” are intended for descriptive purposes only and are not to be construed as indicating or implying relative importance. The term “a plurality of” refers to two or more, unless specifically defined otherwise.

The foregoing descriptions are merely exemplary embodiments of the present disclosure, and are not intended to limit the present disclosure. Within the spirit and principles of the disclosure, any modifications, equivalent substitutions, improvements, etc., are within the protection scope of the present disclosure.

What is claimed is:

1. A method for manufacturing a thin film transistor, comprising:
forming a semiconductor thin film on a base substrate, wherein the semiconductor thin film covers the entire base substrate and is at least configured to form an active layer of the thin film transistor through a patterning process subsequently;
forming a patterned source-drain layer on the base substrate formed with the semiconductor thin film, wherein the source-drain layer at least comprises a source and a drain of the thin film transistor;
forming a conductive thin film on the base substrate formed with the source-drain layer, wherein the conductive thin film covers the entire base substrate and is at least configured to form a protective electrode layer covering the source and the drain through a patterning processing subsequently; and
performing the patterning process on the semiconductor thin film and the conductive thin film simultaneously to acquire the active layer formed of the semiconductor thin film and the protective electrode layer formed of the conductive thin film, and processing the protective electrode layer such that a portion of the protective electrode layer covering the source is insulated from a portion of the protective electrode layer covering the drain.

2. The method according to claim 1, wherein performing the patterning process on the semiconductor thin film and the conductive thin film simultaneously comprises:
forming a photoresist layer on the conductive thin film, and performing exposure and development on the photoresist layer to acquire a photoresist pattern, wherein the photoresist pattern is provided with a first photoresist region, a second photoresist region and a photoresist completely-removed region, wherein photoresist in the first photoresist region covers the source and the drain, photoresist in the second photoresist region covers an area between the source and the drain, a thickness of the photoresist in the first photoresist region is greater than a thickness of the photoresist in the second photoresist region, and no photoresist exists in the photoresist completely-removed region;
performing wet etching on the semiconductor thin film and the conductive thin film simultaneously to remove a portion, corresponding to the photoresist completely-removed region, of the semiconductor thin film and a portion, corresponding to the photoresist completely-removed region, of the conductive thin film, so as to form the active layer and the protective electrode layer; and
removing the photoresist in the second photoresist region and removing a portion, corresponding to the second photoresist region, of the protective electrode layer by dry etching, to form a first protective electrode covering the source and a second protective electrode covering the drain, wherein the first protective electrode and the second protective electrode are disconnected from each other.

3. The method according to claim 2, wherein
a first orthographic projection of the source on the base substrate is within a second orthographic projection of photoresist covering the source in the first photoresist region on the base substrate, and a distance between an outer boundary of the first orthographic projection and an outer boundary of the second orthographic projection is greater than a preset distance threshold;
a third orthographic projection of the drain on the base substrate is within a fourth orthographic projection of photoresist covering the drain in the first photoresist region on the base substrate, and a distance between an outer boundary of the third orthographic projection and an outer boundary of the fourth orthographic projection is greater than a preset distance threshold; and
after the protective electrode layer is formed, the protective electrode layer covers a side surface of the source and covers a side surface of the drain.

4. The method according to claim 2, wherein
a first orthographic projection of the source on the base substrate is within a second orthographic projection of photoresist covering the source in the first photoresist region on the base substrate, and an outer boundary of the first orthographic projection coincides with an outer boundary of the second orthographic projection;
a third orthographic projection of the drain on the base substrate is within a fourth orthographic projection of photoresist covering the drain in the first photoresist region on the base substrate, and an outer boundary of the third orthographic projection coincides with an outer boundary of the fourth orthographic projection; and
after the protective electrode layer is formed, a side surface of the source away from the drain is flush with one side surface of the protective electrode layer, and a side surface of the drain away from the source is flush with the other side surface of the protective electrode layer.

5. The method according to claim 3, wherein the protective electrode layer comprises a first portion and a second portion, wherein the first portion is in contact with the source and faces the drain, the second portion is in contact with the drain and faces the source, and the second photoresist region is disposed between the first portion and the second portion; and
removing the photoresist in the second photoresist region and removing the portion, corresponding to the second photoresist region, of the protective electrode layer by dry etching comprises:
removing photoresist between the first portion and the second portion and thinning the photoresist in the first photoresist region by dry etching; and
removing a portion, between the first portion and the second portion, of the protective electrode layer by dry etching to expose the active layer, so as to form the first protective electrode and the second protective electrode.

6. The method according to claim 5, wherein after removing the portion, between the first portion and the second portion, of the protective electrode layer by dry etching to expose the active layer, the method further comprises:
performing surface treatment on the active layer with plasma, to adjust concentration of oxygen vacancies in the active layer.

7. The method according to claim 6, wherein the plasma comprises at least one of oxygen gas and nitrous oxide gas.

8. The method according to claim 6, wherein after performing the surface treatment on the active layer with plasma, the method further comprises:
removing the photoresist in the first photoresist region, and forming a passivation layer on the first protective electrode and the second protective electrode.

9. The method according to claim 1, wherein prior to forming the semiconductor thin film on the base substrate, the method further comprises:
sequentially forming a gate and a gate insulating layer on the base substrate, wherein an orthographic projection of the active layer on the base substrate is within an orthographic projection of the gate on the base substrate.

10. A thin film transistor, comprising:
an active layer disposed on a side of a base substrate;
a source-drain layer disposed on a side of the active layer away from the base substrate, wherein the source-drain layer at least comprises a source and a drain; and
a protective electrode layer disposed on a side of the source-drain layer away from the base substrate, wherein the protective electrode layer covers the source and the drain, and a portion of the protective electrode layer covering the source is insulated from a portion of the protective electrode layer covering the drain.

11. The thin film transistor according to claim 10, wherein the protective electrode layer comprises a first protective electrode covering the source and a second protective electrode covering the drain, the first protective electrode and the second protective electrode being disconnected from each other.

12. The thin film transistor of claim 11, wherein the first protective electrode covers a side surface of the source, and the second protective electrode covers a side surface of the drain.

13. The thin film transistor of claim 11, wherein a side surface of the first protective electrode is flush with a side surface of the source, and a side surface of the second protective electrode is flush with a side surface of the drain.

14. The thin film transistor of claim 11, wherein a side surface of the first protective electrode away from the second protective electrode is flush with one side surface of the active layer, and a side surface of the second protective electrode away from the first protective electrode is flush with the other side surface of the active layer.

15. The thin film transistor of claim 14, wherein orthographic projections of the source and the drain on the base substrate are within an orthographic projection of the active layer on the base substrate.

16. The thin film transistor of claim 10, further comprising: a third protective electrode disposed between the active layer and the source, and a fourth protective electrode disposed between the active layer and the drain.

17. The thin film transistor according to claim 16, wherein a material of the source-drain layer comprises metal copper, and a material of the protective electrode layer comprises a molybdenum-niobium alloy.

18. The thin film transistor according to claim 16, further comprising: a gate disposed on a side of the active layer close to the base substrate, and a gate insulating layer disposed between the gate and the active layer.

19. A display panel, comprising: a base substrate, and a plurality of thin film transistors disposed on the base substrate, wherein the thin film transistor comprises:
an active layer disposed on a side of the base substrate;
a source-drain layer disposed on a side of the active layer away from the base substrate, wherein the source-drain layer at least comprises a source and a drain; and
a protective electrode layer disposed on a side of the source-drain layer away from the base substrate, wherein the protective electrode layer covers the source and the drain, and a portion of the protective electrode layer covering the source is insulated from a portion of the protective electrode layer covering the drain.

20. A display device, comprising: a power supply assembly and the display panel according to claim 19, wherein
the power supply assembly is configured to supply power to the display panel.
